(19) United States
(12) Patent Application Publication
(10) Pub. No.: US 2022/0157564 A1
(43) Pub. Date: May 19, 2022

(54) PLASMA PROCESSING APPARATUS AND PLASMA PROCESSING METHOD

(71) Applicant: Tokyo Electron Limited, Tokyo (JP)

(72) Inventors: Ken YOSHIDA, Miyagi (JP); Kazunori KONO, Miyagi (JP)

(73) Assignee: Tokyo Electron Limited, Tokyo (JP)

(21) Appl. No.: 17/522,939

(22) Filed: Nov. 10, 2021

(30) Foreign Application Priority Data
Nov. 13, 2020 (JP) 2020-189205

(51) Int. Cl. H01J 37/32

(52) U.S. Cl. CPC H01J 37/32183

(57) ABSTRACT

A plasma processing apparatus includes a first electrode in a substrate support in a chamber, a matcher coupled to the first electrode, a high frequency power supply, and a controller. The matcher includes a lower circuit in which a plurality of lower series circuits each including a capacitor and a switching element are coupled to each other in parallel and an upper circuit in which a plurality of upper series circuits each including a capacitor and a switching element are coupled to each other in parallel. The controller is configured to control the matcher to set the switching element to set one circuit of the lower circuit or the upper circuit, to wait until an amount of change in impedance becomes stable, the impedance changing depending on the setting, and to set the switching element to set another circuit of the lower circuit or the upper circuit.

### CROSS-REFERENCE TO RELATED APPLICATION

The present application claims priority to and incorporates by reference the entire contents of Japanese Patent Application No. 2020-189205 filed in Japan on Nov. 13, 2020.

### FIELD

Exemplary embodiments disclosed herein relates to a plasma processing apparatus and a plasma processing method.

### BACKGROUND

In a plasma processing apparatus, electrodes provided in a chamber are supplied with high frequency power from a high frequency power supply, allowing plasma to be generated in the chamber to perform plasma processing on a target to be processed such as a substrate. A matcher is provided between the high frequency power supply and one of the electrodes. The matcher is configured to cause an impedance on a load side to match to an output impedance of the high frequency power supply. Known examples of such a matcher as explained above include mechanically controlled matchers each configured to cause a motor to adjust a variable capacitor and electronically controlled matchers each configured to electronically control switching elements forming, with capacitors, a plurality of series circuits coupled to each other in parallel.
Patent Literature 1: Japanese Laid-open Patent Publication No. 2012-142285
Patent Literature 2: Japanese Laid-open Patent Publication No. 2019-186098

The present disclosure provides a plasma processing apparatus and a plasma processing method that make it possible to secure stable plasma, and to promptly attain matching.

### SUMMARY

According to an aspect of a present disclosure, a plasma processing apparatus including: a chamber; a substrate support disposed in the chamber; a first electrode disposed in the substrate support; a matcher coupled to the first electrode; a high frequency power supply coupled to the matcher; and a control part, wherein the matcher includes a lower circuit in which a plurality of lower series circuits each including a capacitor and a switching element are coupled to each other in parallel, and an upper circuit in which a plurality of upper series circuits each including a capacitor and a switching element are coupled to each other in parallel, the control part is configured to control the matcher to set the switching element in each of the lower series circuits or the upper series circuits to an on state or an off state to set one circuit of the lower circuit or the upper circuit, the control part is configured to control the matcher to wait until an amount of change in impedance viewed from the matcher toward the chamber becomes stable, the impedance changing depending on the setting of the lower circuit or the upper circuit, and the control part is configured to control the matcher to set the switching element in each of the lower series circuits or the upper series circuits to the on state or the off state to set another circuit of the lower circuit or the upper circuit, the other circuit being different from the one circuit.

### BRIEF DESCRIPTION OF DRAWINGS

FIG. 1 is a view illustrating an example of a plasma processing apparatus according to an embodiment of the present disclosure;

FIG. 2 is a view illustrating an example of a high frequency power supply and a matcher according to the embodiment;

FIG. 3 is a view illustrating an example of a matching circuit in the matcher according to the embodiment;

FIG. 4 is a view illustrating an example of circuit blocks in the matching circuit;

FIG. 5 is a view illustrating an example of a monitor cycle when switching of capacitors takes place once;

FIG. 6 is a view illustrating an example of a change in capacitance when switching of the capacitors takes place once;

FIG. 7 is a view illustrating an example of a monitor cycle when switching of the capacitors to take place is divided into two times;

FIG. 8 is a view illustrating an example of changes in capacitance when switching of the capacitors to take place is divided into two times;

FIG. 9 is a view illustrating an example of experiment results from an experimental example and a comparative example according to the embodiment;

FIG. 10 is a view illustrating an example of a comparison between a plasma load and an inductance-capacitance-resistance (LCR) load for Γ; and

FIG. 11 is a view illustrating an example of a matching circuit in a matcher according to an alternative example.

### DESCRIPTION OF EMBODIMENTS

An exemplary embodiment of a plasma processing apparatus and a plasma processing method disclosed in the present application will be explained below in detail with reference to the accompanying drawings. The present invention is not limited to the embodiment explained below.

An electronically controlled matcher is able to promptly change an impedance. However, such a matcher may not able to fully attain matching under a certain condition, leading to a phenomenon where a switching element is switched repeatedly between on and off. This phenomenon is called hunting, where a capacitance value constantly changes. A possible reason of this hunting is that, in an electronically controlled matcher, a change in capacitance is discontinuous, that is, such a change does not always become linear, in which the impedance jumps to another impedance that differs from an originally intended one for a short period of time under a certain combination, and, in response to this, the electronically controlled matcher tries to further attain matching. Furthermore, since the electronically controlled matcher operates faster than a change in plasma, the electronically controlled matcher tries to attain matching before the change in plasma becomes stable, leading to unstable plasma. Therefore, what is expected is to secure stable plasma, and to promptly attain matching.

### Configuration of Plasma Processing Apparatus 1

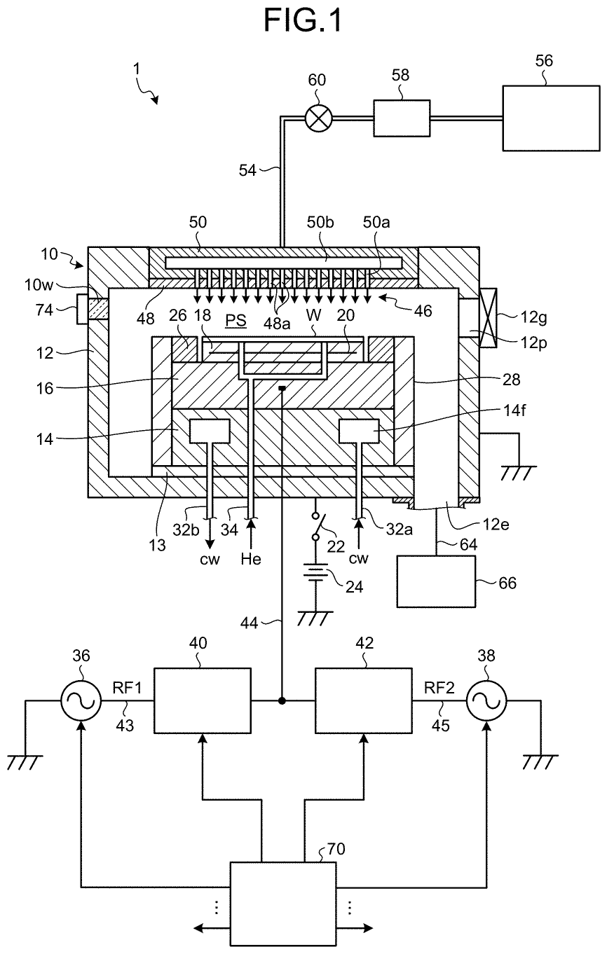

FIG. 1 is a view illustrating an example of a plasma processing apparatus according to an embodiment of the present disclosure. The plasma processing apparatus 1 illustrated in FIG. 1 is a capacitively coupled plasma processing apparatus. The plasma processing apparatus 1 includes a chamber 10 providing an internal space.

The chamber 10 has a chamber main body 12 having a substantially cylindrical shape. That is, the internal space of the chamber 10 represents a space inside the chamber main body 12. The chamber main body 12 is made of a material such as aluminum. Its inner wall surface has undergone an anodic oxidation treatment. The chamber main body 12 is grounded. An opening 12p is formed on a side wall of the chamber main body 12. A substrate W passes through the opening 12p when it is transferred between the internal space of the chamber 10 and outside the chamber 10. It is possible to open or close the opening 12p with a gate valve 12g. The gate valve 12g is provided along the side wall of the chamber main body 12.

A wall part of the chamber 10, such as a side wall of the chamber main body 12, is provided with a window 10w. The window 10w is formed from an optically transparent member. Light generated in the chamber 10 passes through the window 10w and exits the chamber 10. The plasma processing apparatus 1 further includes an optical sensor 74. The optical sensor 74 is disposed on the outside of the chamber 10 to face the window 10w. The optical sensor 74 is configured to monitor an amount of luminescence in the internal space (e.g., a processing region PS explained later) of the chamber 10. The optical sensor 74 is, for example, a luminescent spectroscopic analyzer. Note that the optical sensor 74 may be provided in the chamber 10.

An insulating plate 13 is provided on a bottom part of the chamber main body 12. The insulating plate 13 is made of ceramic, for example. A supporting stand 14 having a substantially columnar shape is provided on the insulating plate 13. A susceptor 16 made of an electrically conductive material such as aluminum is provided on the supporting stand 14. The susceptor 16 serves as a lower electrode. The susceptor 16 is electrically coupled to a high frequency power supply explained later for generating plasma in the chamber 10.

An electrostatic chuck 18 is provided on the susceptor 16. The electrostatic chuck 18 is configured to hold the substrate W mounted thereon. The electrostatic chuck 18 has a main body and an electrode 20. The main body of the electrostatic chuck 18 is made of an insulating material and has a substantially disc shape. The electrode 20 is an electrically conductive film, and is provided in the main body of the electrostatic chuck 18. A direct current (DC) power supply 24 is electrically coupled, via a switch 22, to the electrode 20. When a DC voltage is applied from the direct current power supply 24 to the electrode 20, electrostatic attraction is generated between the substrate W and the electrostatic chuck 18. The generated electrostatic attraction causes the substrate W to be attracted to the electrostatic chuck 18, and to be held by the electrostatic chuck 18.

An edge ring 26 is disposed around the electrostatic chuck 18 and on the susceptor 16. The edge ring 26 is disposed to surround edges of the substrate W. An inner wall member 28 having a cylindrical shape is attached to outer peripheral surfaces of the susceptor 16 and the supporting stand 14. The inner wall member 28 is made of quartz, for example.

A flow channel 14f is formed in the supporting stand 14. The flow channel 14f spirally extends with respect to a central axis line extending in a perpendicular direction, for example. A heat exchange medium cw (e.g., a coolant such as cooling water.) is supplied from a supply device (e.g., a chiller unit.) provided outside the chamber 10, via a pipe 32a, to the flow channel 14f. The heat exchange medium supplied to the flow channel 14f is collected, via a pipe 32b, to the supply device. As a temperature of the heat exchange medium is adjusted by the supply device, a temperature of the substrate W is adjusted. Furthermore, a gas supply line 34 is provided in the plasma processing apparatus 1. The gas supply line 34 is provided to supply heat transfer gas (e.g., He gas) between an upper surface of the electrostatic chuck 18 and a reverse face of the substrate W.

An electric conductor 44 (e.g., a power supply rod.) is coupled to the susceptor 16. A high frequency power supply 36 is coupled, via a matcher 40, to the electric conductor 44. Furthermore, a high frequency power supply 38 is coupled, via a matcher 42, to the electric conductor 44. That is, the high frequency power supply 36 is coupled, via the matcher 40 and the electric conductor 44, to the lower electrode. Furthermore, the high frequency power supply 38 is coupled, via the matcher 42 and the electric conductor 44, to the lower electrode. Instead of the lower electrode, the high frequency power supply 36 may be coupled, via the matcher 40, to an upper electrode explained later. Note that the plasma processing apparatus 1 may not include either the set of the high frequency power supply 36 and the matcher 40 or the set of the high frequency power supply 38 and the matcher 42.

The high frequency power supply 36 is configured to output high frequency power RF1 for generating plasma. A basic frequency f_{B1} of the high frequency power RF1 is 100 MHz, for example. The high frequency power supply 38 is configured to output high frequency power RF2 for attracting ions from plasma to the substrate W. A frequency of the high frequency power RF2 is lower than the frequency of the high frequency power RF1. A basic frequency f_{B2} of the high frequency power RF2 is 13.56 MHz, for example.

The matcher 40 includes a circuit configured to cause an impedance on a load side (e.g., a lower electrode side) of the high frequency power supply 36 to match to an output impedance of the high frequency power supply 36. The matcher 42 includes a circuit configured to cause an impedance on a load side (a lower electrode side) of the high frequency power supply 38 to match to an output impedance of the high frequency power supply 38. The matcher 40 and the matcher 42 respectively are electronically controlled matchers.

The matcher 40 and the electric conductor 44 form a part of a power supply line 43. The high frequency power RF1 is supplied, via the power supply line 43, to the susceptor 16. The matcher 42 and the electric conductor 44 form a part of a power supply line 45. The high frequency power RF2 is supplied, via the power supply line 45, to the susceptor 16.

An upper electrode 46 serves as a top part of the chamber 10. The upper electrode 46 is provided to close an opening at an upper end of the chamber main body 12. The internal space of the chamber 10 has the processing region PS. The processing region PS represents a space between the upper electrode 46 and the susceptor 16. The plasma processing apparatus 1 uses a high frequency electric field generated between the upper electrode 46 and the susceptor 16 to generate plasma in the processing region PS. The upper electrode 46 is grounded. Note that, in a case where the high frequency power supply 36 is coupled, via the matcher 40, to the upper electrode 46, instead of the lower electrode, the upper electrode 46 is not grounded, and the upper electrode 46 and the chamber main body 12 are electrically separated away from each other.

The upper electrode 46 has a top plate 48 and a supporting body 50. The top plate 48 is formed with a plurality of gas blowout holes 48a. The top plate 48 is made of a material based on silicon such as Si or SiC. The supporting body 50 is a member detachably supporting the top plate 48, is made of aluminum, and has undergone an anodic oxidation treatment on its top face.

A gas buffer chamber 50b is formed in the supporting body 50. Furthermore, the supporting body 50 is formed with a plurality of gas holes 50a. The gas holes 50a respectively extend from the gas buffer chamber 50b and are in communication with the gas blowout holes 48a. A gas supply pipe 54 is coupled to the gas buffer chamber 50b. A gas source 56 is coupled, via a flow controller 58 (e.g., a mass flow controller.) and an opening-and-closing valve 60, to the gas supply pipe 54. Gas is supplied from the gas source 56, via the flow controller 58, the opening-and-closing valve 60, the gas supply pipe 54, the gas buffer chamber 50b, and the gas blowout holes 48a, to the internal space of the chamber 10. A volume of flowing gas to be supplied from the gas source 56 to the internal space of the chamber 10 is adjusted by the flow controller 58.

Below a space between the susceptor 16 and the side wall of the chamber main body 12, an exhaust port 12e is provided to the bottom part of the chamber main body 12. An exhaust pipe 64 is coupled to the exhaust port 12e. The exhaust pipe 64 is coupled to an exhaust device 66. The exhaust device 66 includes a pressure adjusting valve and a vacuum pump such as a turbomolecular pump. The exhaust device 66 is configured to decompress the internal space of the chamber 10 to specified pressure.

The plasma processing apparatus 1 further includes a main control part 70. The main control part 70 includes one or more microcomputers. The main control part 70 includes a memory such as a read only memory (ROM) and a random access memory (RAM) and a processor such as a central processing unit (CPU). The main control part 70 may include an input device such as a keyboard, a display device, and an input-and-output interface for signals. The processor of the main control part 70 is configured to read and execute software (computer programs) stored in the memory and follows recipe information to control the components of the plasma processing apparatus 1. The processor of the main control part 70 controls, for example, individual operations of the high frequency power supply 36, the high frequency power supply 38, the matcher 40, the matcher 42, the flow controller 58, the opening-and-closing valve 60, the exhaust device 66, and the optical sensor 74, and controls operations (sequences) of the whole plasma processing apparatus 1.

When plasma processing takes place in the plasma processing apparatus 1, the gate valve 12g is first opened. Next, the substrate W is carried, via the opening 12p, into the chamber 10, and is placed on the electrostatic chuck 18. Then, the gate valve 12g is closed. Next, processing gas is supplied from the gas source 56 to the internal space of the chamber 10. The exhaust device 66 is then operated to set pressure in the internal space of the chamber 10 to specified pressure. Furthermore, the high frequency power RF1 and/or the high frequency power RF2 are or is supplied to the susceptor 16. Furthermore, a DC voltage from the direct current power supply 24 is applied to the electrode 20 of the electrostatic chuck 18, allowing the electrostatic chuck 18 to hold the substrate W. Then, the processing gas is excited in a high frequency electric field formed between the susceptor 16 and the upper electrode 46. As a result, plasma is generated in the processing region PS.

### Details of High Frequency Power Supply 36 and Matcher 40

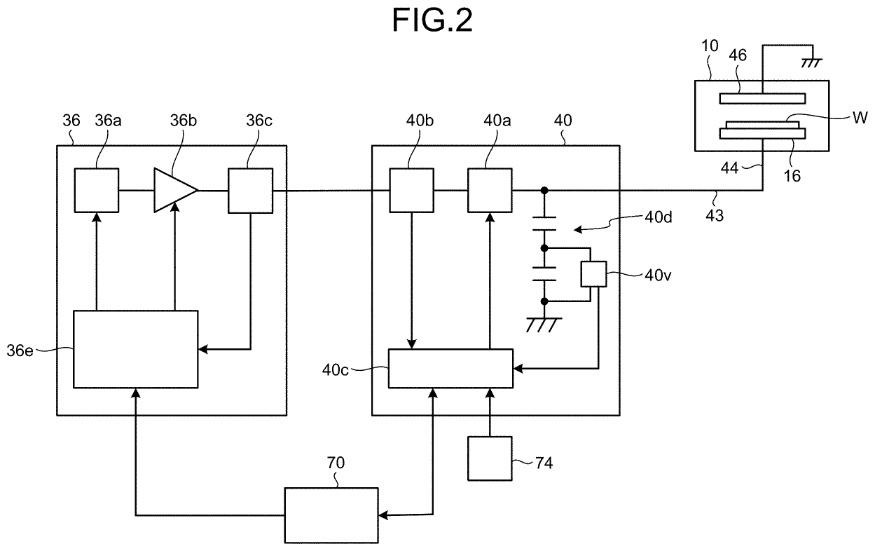

Next, details of the high frequency power supply and the matcher will be explained below with reference to FIGS. 2 to 4. Note that, since the high frequency power supply 38 and the matcher 42 are identical to the high frequency power supply 36 and the matcher 40, excluding the frequency of high frequency power, respective explanations are omitted.

FIG. 2 is a view illustrating an example of the high frequency power supply and the matcher according to the present embodiment. As illustrated in FIG. 2, the high frequency power supply 36 includes an oscillator 36a, a power amplifier 36b, a power sensor 36c, and a power supply controller 36e. The power supply controller 36e includes a processor such as a CPU and a memory. The power supply controller 36e is configured to utilize signals provided from the main control part 70 and the power sensor 36c to provide control signals respectively to the oscillator 36a and the power amplifier 36b to control the oscillator 36a and the power amplifier 36b.

The signals that the main control part 70 provides to the power supply controller 36e are a first power level setting signal and a first frequency setting signal. The first power level setting signal represents a signal specifying a power level of the high frequency power RF1. The first frequency setting signal represents a signal specifying a set frequency of the high frequency power RF1.

The power supply controller 36e controls and causes the oscillator 36a to output a high frequency signal having the set frequency specified by the first frequency setting signal. An output of the oscillator 36a is coupled to an input of the power amplifier 36b. The high frequency signal outputted from the oscillator 36a is inputted to the power amplifier 36b. The power amplifier 36b is configured to amplify the inputted high frequency signal to generate, from the inputted high frequency signal, the high frequency power RF1 having the power level specified by the first power level setting signal. The power amplifier 36b outputs the generated high frequency power RF1.

The power sensor 36c is provided behind the power amplifier 36b. The power sensor 36c includes a directional coupler, a traveling wave detector, and a reflective wave detector. In the power sensor 36c, the directional coupler is configured to output a part of a traveling wave of the high frequency power RF1 to the traveling wave detector, and to output a reflective wave to the reflective wave detector. A signal identifying the frequency of the high frequency power RF1 is inputted from the power supply controller 36e to the power sensor 36c. The traveling wave detector of the power sensor 36c is configured to generate a measured value of a power level of a component having a frequency identical to the set frequency of the high frequency power RF1, in all frequency components in the traveling wave, that is, a measured value Pf₁₁ of the power level of the traveling wave. The measured value Pf₁₁ is inputted to the power supply controller 36e for a power feedback purpose.

The reflective wave detector of the power sensor 36c is configured to generate a measured value of a power level of a component having a frequency identical to the frequency of the high frequency power RF1, in all frequency components of the reflective wave, that is, a measured value Pr₁₁ of the power level of the reflective wave. Furthermore, the reflective wave detector of the power sensor 36c is configured to generate a measured value of a total power level of all the frequency components of the reflective wave, that is, a measured value Pr₁₂ of the power level of the reflective wave. The measured value Pr₁₁ is outputted to the main control part 70 for a monitor display purpose. The measured value Pr₁₂ is outputted to the power supply controller 36e for protecting the power amplifier 36b.

The matcher 40 includes a matching circuit 40a, a sensor 40b, a controller 40c, a voltage dividing circuit 40d, and a voltage monitor 40v. The matching circuit 40a is an electronically controlled matching circuit.

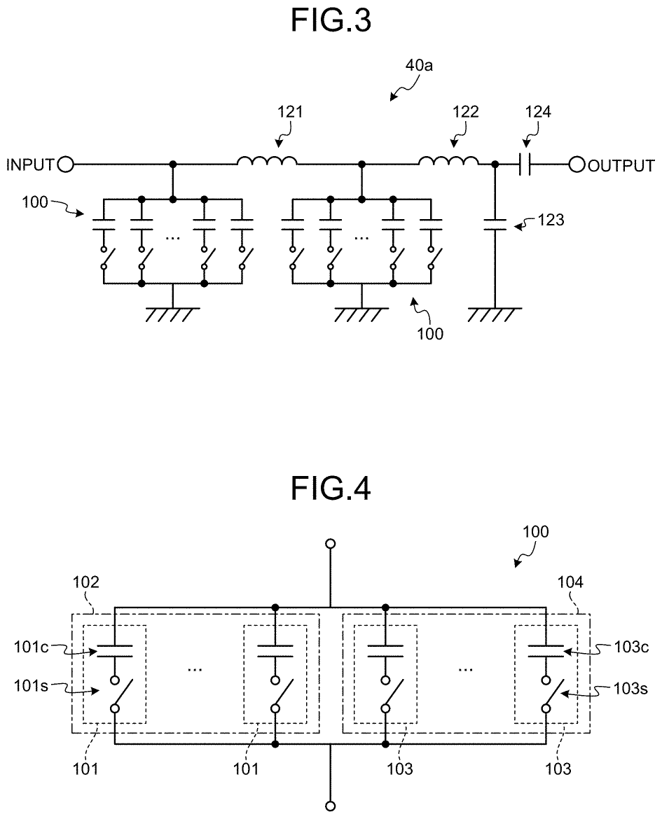

FIG. 3 is a view illustrating an example of the matching circuit of the matcher according to the present embodiment. As illustrated in FIG. 3, the matching circuit 40a includes circuit blocks 100 forming a pair of circuits in each of which a plurality of series circuits each including a capacitor and a switching element are coupled to each other in parallel, coils 121, 122, and capacitors 123, 124. In the matching circuit 40a, one of the circuit blocks 100, the coil 121, another one of the circuit blocks 100, the coil 122, the capacitor 123, and the capacitor 124 are coupled in order from an Input side to which the high frequency power supply 36 is coupled. The susceptor 16 is coupled, via the electric conductor 44, to an Output side of the capacitor 124.

The two circuit blocks 100 are each coupled in parallel between a node between the high frequency power supply 36 and an electrode on a load side (e.g., the susceptor 16 serving as the lower electrode.) and a ground. The coil 121 is coupled in series to the nodes between the two circuit blocks 100. The coil 122 and the capacitor 124 are coupled in series to the nodes between the circuit block 100 lying adjacent to the Output side and the Output side. The capacitor 123 is coupled in parallel between the node between the coil 122 and the capacitor 124 and the ground.

FIG. 4 is a view illustrating an example of the circuit blocks in the matching circuit. As illustrated in FIG. 4, the circuit blocks 100 each include a lower circuit 102 and an upper circuit 104. In the lower circuit 102 being configured, a plurality of lower series circuits 101 each including a capacitor 101c and a switching element 101s are coupled to each other in parallel. The capacitor 101c and the switching element 101s are coupled to each other in series. In the upper circuit 104 being configured, a plurality of upper series circuits 103 each including a capacitor 103c and a switching element 103s are coupled to each other in parallel. The capacitor 103c and the switching element 103s are coupled to each other in series. For the switching elements 101s and the switching elements 103s, it is possible to use positive intrinsic negative (PIN) diodes, transistors, or thyristors, for example.

That is, in each of the circuit blocks 100, the lower series circuits 101 and the upper series circuits 103 are coupled to each other in parallel, allowing, in a synthesized capacitance of each of the circuit blocks 100, the lower series circuits 101 of the lower circuit 102 to represent lower digits, while the upper series circuits 103 of the upper circuit 104 to represent higher digits. In the present embodiment, for example, the lower series circuits 101 of the lower circuit 102 represent digits of a binary number, while the upper series circuits 103 of the upper circuit 104 each represent an identical degree of weighting to that for a synthesized capacitance of the lower circuit 102.

Now back to the explanation with reference to FIG. 2. The controller 40c includes a processor and a memory, for example. The controller 40c is configured to operate under the control of the main control part 70. The controller 40c is configured to utilize a measured value inputted from the sensor 40b.

The sensor 40b includes a voltage detector and a current detector to detect a voltage waveform and a current waveform of the high frequency power RF1 transmitted on the power supply line 43. The sensor 40b is configured to extract, from the detected voltage waveform and the detected current waveform, only components of the set frequency of the high frequency power RF1 to generate a voltage waveform signal having undergone filtering and a current waveform signal having undergone filtering. The sensor 40b outputs, to the controller 40c, the generated voltage waveform signal having undergone filtering and the generated current waveform signal having undergone filtering.

The controller 40c calculates an impedance (hereinafter referred to as an “impedance Z1”.) on the load side of the high frequency power supply 36. The controller 40c calculates, on the basis of a voltage V1 and a current I1 identified by the voltage waveform signal having undergone filtering and the current waveform signal having undergone filtering, the impedance Z1 using Z1=V1/I1. The controller 40c controls the switching elements 101s and the switching elements 103s of the matching circuit 40a to cause the calculated impedance Z1 to be closer to an output impedance (a matching point) of the high frequency power supply 36.

The controller 40c determines whether plasma is generated in the chamber 10 while the high frequency power RF1 is supplied from the high frequency power supply 36. That is, the controller 40c determines, after the high frequency power RF1 is supplied from the high frequency power supply 36, and after the high frequency power RF1 is detected in the sensor 40b, whether plasma is generated in the chamber 10.

The controller 40c instructs, when it is determined that no plasma is generated in the chamber 10, the power supply controller 36e to adjust a frequency of the high frequency power RF1 to set a reactance on the load side to zero or to a value closer to zero. The reactance on the load side is identified from the impedance Z1. The controller 40c sends an instruction to the power supply controller 36e directly or via the main control part 70. Specifically, the controller 40c calculates, when it is determined that no plasma is generated in the chamber 10, a set frequency used to set the reactance on the load side to zero or to a value closer to zero, on a Smith chart. The controller 40c sends an instruction to the power supply controller 36e to adjust the frequency of the high frequency power RF1 to the calculated set frequency. The power supply controller 36e is configured to control the oscillator 36a to adjust, to the set frequency instructed by the controller 40c, a frequency of a high frequency signal to be outputted. As the frequency of the high frequency signal to be outputted by the oscillator 36a is adjusted to the set frequency, the frequency of the high frequency power RF1 is adjusted to the set frequency.

The controller 40c may change, when it is determined that no plasma is generated in the chamber 10 even when the frequency of the high frequency power RF1 is adjusted to a set frequency, the frequency of the high frequency power RF1 causing plasma to be generated in the chamber 10. In this case, the frequency of the high frequency power RF1 is swept within a predetermined range, for example.

The controller 40c calculates, for determining whether plasma is generated in the chamber 10, one or more parameters in which the fact that plasma is generated in the chamber 10 is reflected. The one or more parameters is or are one or more parameters selected from a phase difference Φ1, a magnitude |Z1| of the impedance Z1, a reflection coefficient Γ1, a power level Pf1 of a traveling wave, a power level Pr1 of a reflective wave, a wave height value Vpp1 of a voltage, and an amount of luminescence in the chamber 10. The controller 40c determines whether plasma is generated by comparing the one or more parameters with corresponding threshold values. Note that the controller 40c may determine that plasma is generated in the chamber 10 when a plurality of parameters are used, and when results of comparison of all the parameters with corresponding parameters indicate that plasma is generated in the chamber 10. Otherwise, the controller 40c may determine that plasma is generated in the chamber 10 when results of comparison of one or more parameters among a plurality of parameters with corresponding parameters indicate that plasma is generated in the chamber 10.

Note that it is possible to calculate, as explained below, respective parameters, which are the phase difference Φ1, the reflection coefficient Γ1, the power level Pf1 of a traveling wave, the power level Pr1 of a reflective wave, the wave height value Vpp1 of a voltage, and an amount of luminescence in the chamber 10.

The phase difference Φ1 represents a phase difference between the voltage V1 and the current I1. The controller 40c is able to calculate the phase difference Φ1 with a below equation (1). Note that X1 and R1 in the equation (1) are defined with a below equation (2). Furthermore, in the equation (2), “j” represents an imaginary number.

Φ1=tan⁻¹(X1/R1) (1)

Z1=R1+jX1 (2)

The controller 40c is able to calculate the reflection coefficient III with a below equation (3). Note that, in the equation (3), Z₀₁ represents a characteristic impedance of the power supply line 43, and is, commonly, 50Ω.

Γ1=(Z1−Z₀₁)/(Z1+Z₀₁) (3)

The power level Pf1 of a traveling wave represents a power level of a traveling wave on the power supply line 43. The power level Pr1 of a reflective wave represents a power level of a reflective wave on the power supply line 43. The controller 40c is able to calculate the power level Pf1 of a traveling wave with a below equation (4). The controller 40c is able to calculate the power level Pr1 of a reflective wave with a below equation (5). Note that, in the equations (4) and (5), P1 represents a difference between a power level of a traveling wave and a power level of a reflective wave, that is, a level of load power. The level P1 of load power is defined by a below equation (6).

Pf1=P1/(1−|Γ1|²) (4)

Pr1=|Γ1|₂P1/(1−|Γ1|²) (5)

P1=Pf1−Pr1=V1I1 cos Φ1 (6)

The wave height value Vpp1 of a voltage represents a wave height value of a voltage on the power supply line 43. The controller 40c is able to acquire the wave height value Vpp1 measured by the voltage monitor 40v. The voltage monitor 40v is configured to calculate, as illustrated in FIG. 2, the wave height value Vpp1 from a measured value of a voltage divided by the voltage dividing circuit 40d. Furthermore, the controller 40c is able to acquire an amount of luminescence in the chamber 10 from the optical sensor 74.

The controller 40c sends, when it is determined that plasma is generated in the chamber 10, an instruction to the power supply controller 36e to set the set frequency of the high frequency power RF1 to the basic frequency f_{B1}. The power supply controller 36e controls, in line with the controller 40c, the oscillator 36a to set, to the basic frequency f_{B1}, a frequency of a high frequency signal to be outputted. As the frequency of the high frequency signal to be outputted is set to the basic frequency f_{B1} by the oscillator 36a, the frequency of the high frequency power RF1 is set to the basic frequency f_{B1}. Furthermore, the controller 40c controls, when it is determined that plasma is generated in the chamber 10, the matching circuit 40a to cause an impedance on the load side of the high frequency power supply 36 to match to an output impedance (the matching point) of the high frequency power supply 36.

### Operation of Matcher 40

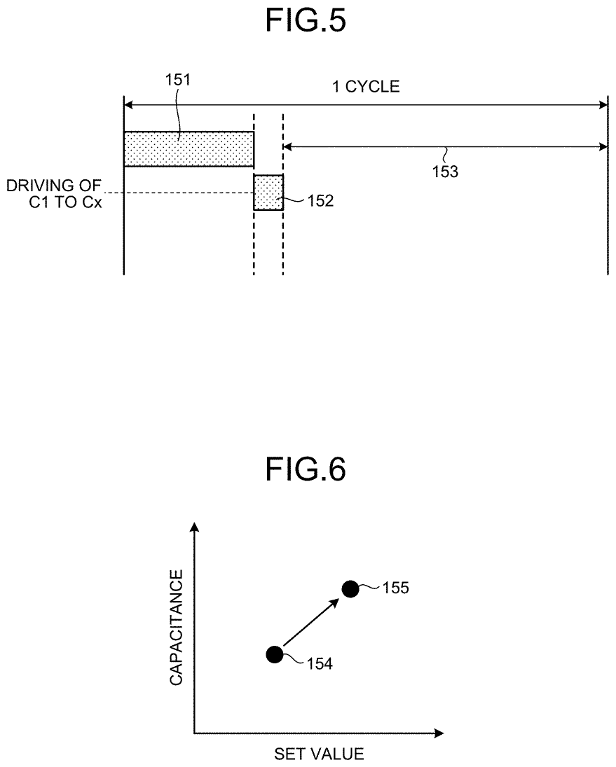

Next, how the matcher 40 operates will be explained below. A case when switching of the capacitors takes place once will first be explained with reference to FIGS. 5 and 6 for a comparison purpose. Note herein that a case when switching of the capacitors takes place once refers to a case when matching is not fully attained under a certain condition.

FIG. 5 is a view illustrating an example of a monitor cycle when switching of the capacitors takes place once. FIG. 6 is a view illustrating an example of a change in capacitance when switching of the capacitors takes place once. As illustrated in FIG. 5, when switching of a plurality of capacitors C1 to Cx takes place once, one cycle of monitor cycles of the matcher includes intervals 151 to 153. The interval 151 represents an interval for performing a matching calculation where it is calculated that which switching elements are to be switched on the basis of data of an impedance measured in a data sampling interval in a previous cycle, that is the interval 153. The interval 152 represents an interval for allowing switching of the capacitors to take place. The interval 153 represents a data sampling interval for impedance, when viewed from the matcher toward the chamber.

As illustrated in FIG. 6, in the switching in FIG. 5, a synthesized capacitance of the capacitors C1 to Cx changes from a capacitance value 154 to a capacitance value 155 in accordance with one change in set value. However, since the change in capacitance is discontinuous, there may be a case where an impedance jumps, under a certain combination, to another impedance for a short period of time at which plasma may disappear. Therefore, there may be cases where hunting occurs and plasma becomes unstable.

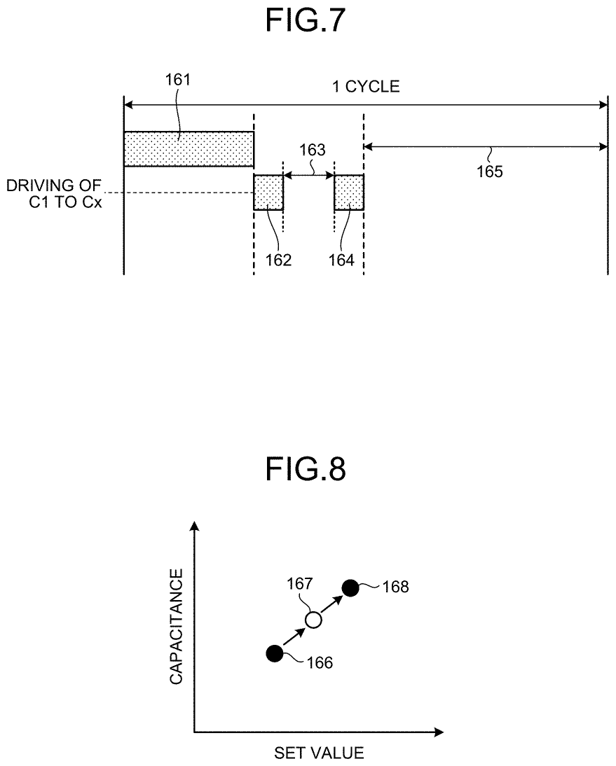

Next, a case when, in the matcher 40 according to the present embodiment, switching of the capacitors to take place is divided into two times will be explained below with reference to FIGS. 7 and 8. FIG. 7 is a view illustrating an example of a monitor cycle when switching of the capacitors to take place is divided into two times. FIG. 8 is a view illustrating an example of changes in capacitance when switching of the capacitors to take place is divided into two times.

As illustrated in FIG. 7, in the matcher 40 controlled by the main control part 70, switching of the capacitors to take place is divided into two times, that is, switching of the capacitors takes place in the lower circuit 102 and the upper circuit 104, in one of the circuit blocks 100, which corresponds to the capacitors C1 to Cx. In this case, one cycle of monitor cycles of the matcher 40 includes intervals 161 to 165. Note that the one cycle of monitor cycles is to 1 ms, for example.

The interval 161 represents an interval for performing a matching calculation where it is calculated that which of the switching elements 101s, 103s are to be switched on the basis of data of an impedance measured in a data sampling interval in the previous cycle, that is the interval 165. The interval 162 represents an interval for allowing switching of the switching elements 101s to take place in the lower circuit 102. The interval 163 represents an interval of waiting until an amount of change in impedance viewed from the matcher 40 toward the chamber 10 becomes stable, which changes when switching of the switching elements 101s of the lower circuit 102 takes place. The interval 163 is to 350 μs or longer, for example. Furthermore, the interval 163 may have a fixed value or a variable value. The interval 164 represents an interval for allowing switching of the switching elements 103s to take place in the upper circuit 104. The interval 165 represents a data sampling interval for impedance, when viewed from the matcher 40 toward the chamber 10.

That is, the main control part 70 controls, in the interval 162, the matcher 40 to set the switching elements 101s, 103s in the lower series circuits 101 or the upper series circuits 103 to an on state or an off state to set one circuit of the lower circuit 102 or the upper circuit 104. Next, the main control part 70 controls, in the interval 163, the matcher 40 to wait until an amount of change in impedance viewed from the matcher 40 toward the chamber 10 becomes stable, which changes depending on the setting of the lower circuit 102 or the upper circuit 104. Next, the main control part 70 controls, in the interval 164, the matcher 40 to set the switching elements 101s, 103s in the lower series circuits 101 or the upper series circuits 103 to the on state or the off state to set another circuit, which differs from the one circuit, of the lower circuit 102 or the upper circuit 104. Therefore, it is possible to secure stable plasma, and to promptly attain matching.

Note that, when a synthesized capacitance of each of the circuit blocks 100 changes in a direction in which the synthesized capacitance increases, carry-over driving is performed, where switching of the lower circuit 102 takes place in the interval 162, and switching of the upper circuit 104 takes place in the interval 164, as explained above. On the other hand, when the synthesized capacitance of each of the circuit blocks 100 changes in a direction in which the synthesized capacitance decreases, borrow driving is performed, where switching of the upper circuit 104 takes place in the interval 162, and switching of the lower circuit 102 takes place in the interval 164. Furthermore, when the synthesized capacitance of each of the circuit blocks 100 changes in a direction in which the synthesized capacitance increases, but a change in the synthesized capacitance of each of the circuit blocks 100 falls within a range of the lower circuit 102, switching of the lower circuit 102 takes place in the interval 162 but switching of neither the lower circuit 102 nor the upper circuit 104 takes place in the interval 164. On the other hand, when the synthesized capacitance of each of the circuit blocks 100 changes in a direction in which the synthesized capacitance decreases, but a change in the synthesized capacitance of each of the circuit blocks 100 falls within the range of the lower circuit 102, switching of neither the lower circuit 102 nor the upper circuit 104 takes place in the interval 162, but switching of the lower circuit 102 takes place in the interval 164.

In other words, when the synthesized capacitance of each of the circuit blocks 100 changes in a direction in which the synthesized capacitance increases, switching of the lower circuit 102 takes place in the interval 162, and switching of the upper circuit 104 takes place in the interval 164. However, when a change in the synthesized capacitance falls within the range of the lower circuit 102, no switching of the interval 164 takes place. On the other hand, when the synthesized capacitance of each of the circuit blocks 100 changes in a direction in which the synthesized capacitance decreases, switching of the upper circuit 104 takes place in the interval 162, and switching of the lower circuit 102 takes place in the interval 164. However, when a change in the synthesized capacitance falls within the range of the lower circuit 102, no switching of the interval 162 takes place. Note that, in the lower circuit 102 and the upper circuit 104, the switching elements 101s or the switching elements 103s are set to the on state or the off state simultaneously or one by one, in accordance with a synthesized capacitance to be set.

As illustrated in FIG. 8, in switching in the matcher 40, the synthesized capacitance of each of the circuit blocks 100 changes from a capacitance value 166 to a capacitance value 167 when switching takes place for the first time in the interval 162. After waiting in the interval 163, the synthesized capacitance of each of the circuit blocks 100 changes from the capacitance value 167 to a capacitance value 168 when switching takes place for the second time in the interval 164. In switching in the matcher 40, after switching of the lower circuit 102 takes place, and after waiting takes place for a period of time indicated by the interval 163, switching of the upper circuit 104 takes place. Therefore, an impedance does not jump to such an impedance at which plasma may disappear.

### Experiment Results

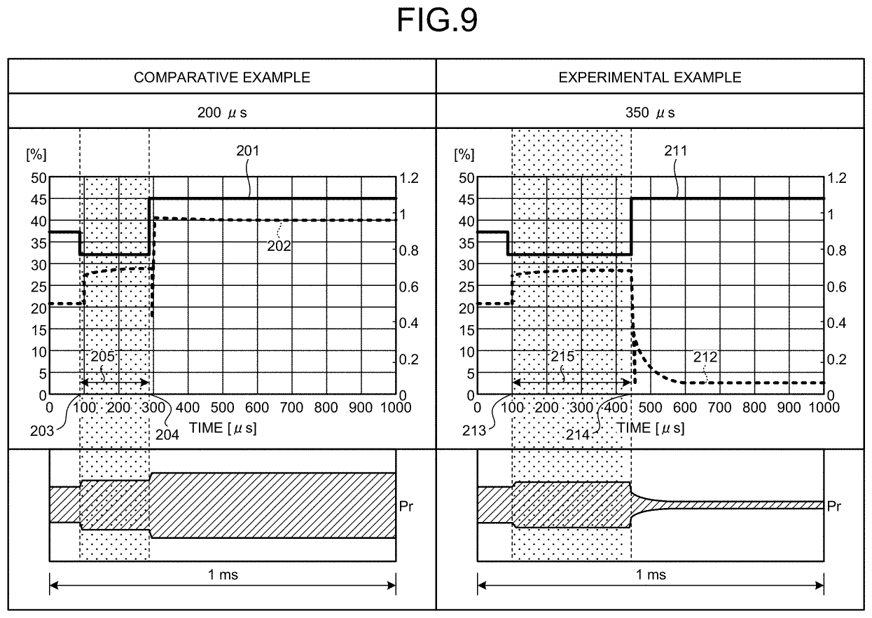

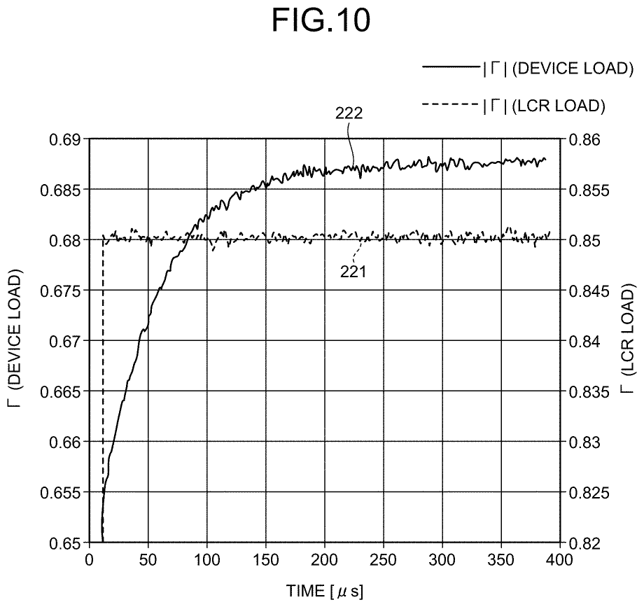

Next, experiment results will be explained below with reference to FIGS. 9 and 10. FIG. 9 is a view illustrating an example of experiment results from an experimental example and a comparative example according to the present embodiment. FIG. 10 is a view illustrating an example of a comparison between a plasma load and an inductance-capacitance-resistance (LCR) load for Γ. Note that FIG. 9 illustrates an example when the synthesized capacitance of each of the circuit blocks 100 changes in a direction in which the synthesized capacitance increases, and switching takes place in the order of the lower circuit 102 and the upper circuit 104.

In FIG. 9, a reflection coefficient Γ and a power level Pr of a reflective wave, when the period of time of the interval 163 in FIG. 7 is changed, are compared with each other. The comparative example in FIG. 9 illustrates a position of the matcher 40, the reflection coefficient Γ, and the power level Pr of the reflective wave, when the period of time of the interval 163 is set to 200 μs. A graph 201 illustrates a position when a movable range of a capacitance of the matcher 40 is set to a range from 0 to 100%. Note that, in the experiment result in FIG. 9, the position of the matcher 40 falls within a range of approximately 30 to 50%. Therefore, those that are at or above 50% are omitted.

A graph 202 illustrates the reflection coefficient Γ. A switching point 203 and a switching point 204 respectively represent timings of switching of the switching elements 101s and the switching elements 103s, which correspond to the interval 162 and the interval 164 in FIG. 7. Note that the switching point 203 and the switching point 204 respectively correspond to start points of the interval 162 and the interval 164. That is, the interval 162 and the interval 164 are each in a state that they are not fully expressed on the graph in FIG. 9 because they are too short. An interval 205 represents a waiting period corresponding to the interval 163 in FIG. 7, and is 200 μs. The power level Pr of the reflective wave indicates that the wider the width, the higher the power level of the reflective wave.

In the comparative example, when the position of the matcher 40 changes from 37% to 32% at the switching point 203, and switching of the lower circuit 102 takes place, the reflection coefficient Γ increases from approximately 0.5 to 0.7, and the power level Pr of the reflective wave increases. After the interval 205, when the position of the matcher 40 changes from 32% to 45% at the switching point 204, and switching of the upper circuit 104 takes place, plasma becomes unstable due to a slow change in impedance of the plasma, causing the reflection coefficient Γ to change to a value closer to 1, and the power level Pr of the reflective wave greatly increases. That is, in the comparative example, no matching in impedance is attained, and accordingly most of the supplied high frequency power RF1 is reflected. That is, plasma may disappear in the chamber 10.

On the other hand, the experimental example in FIG. 9 illustrates a position of the matcher 40, the reflection coefficient Γ, and the power level Pr of a reflective wave, when the period of time of the interval 163 is set to 350 μs. A graph 211 illustrates a position when a movable range of a capacitance of the matcher 40 is set to a range from 0 to 100%.

A graph 212 illustrates the reflection coefficient Γ. A switching point 213 and a switching point 214 respectively represent timings of switching of the switching elements 101s and the switching elements 103s, which correspond to the interval 162 and the interval 164 in FIG. 7. Note that the switching point 213 and the switching point 214 respectively correspond to the start points of the interval 162 and the interval 164. An interval 215 represents a waiting period corresponding to the interval 163 in FIG. 7, and is 350 μs.

In the experimental example, when the position of the matcher 40 changes from 37% to 32% at the switching point 213, and when switching of the lower circuit 102 takes place, the reflection coefficient Γ changes from approximately 0.5 to 0.7, and the power level Pr of the reflective wave increases. After the interval 215, when the position of the matcher 40 changes from 32% to 45% at the switching point 214, and when switching of the upper circuit 104 takes place, plasma becomes stable due to that a change in impedance of the plasma subsides to some extent, and the reflection coefficient Γ decreases to 0.1 or below. Therefore, the power level Pr of the reflective wave greatly decreases. That is, in the experimental example, matching in impedance is attained, and the supplied high frequency power RF1 is supplied to the chamber 10. That is, plasma is maintained in the chamber 10.

According to the experiment results explained above, it is conceivable that a length of a waiting period corresponding to the interval 163 contributes to stable plasma. It is possible to verify this contribution by comparing, as illustrated in FIG. 10, a change in the reflection coefficient Γ in an LCR load including a coil, a capacitor, and a resistor with the reflection coefficient Γ in a device load configured based on plasma. That is, the reflection coefficient Γ of the LCR load, as illustrated in the graph 221, changes for a period of 1 μs or shorter during its rising period, but the reflection coefficient Γ of the device load, as illustrated in the graph 222, changes for a period of 100 μs or longer during its rising period. Furthermore, it takes approximately 300 μs until a change of the graph 222 during its rising period subsides to attain a steady state. Therefore, it is preferable that a waiting period correspond to a period until an impedance reaches 80% or higher of its steady state value. As explained above, in the present embodiment, after switching of the lower circuit 102 takes place, and after a waiting period of 350 μs or longer has passed, switching of the upper circuit 104 takes place. Therefore, it is possible to secure stable plasma, and to promptly attain matching.

### Alternative Example

In the embodiment explained above, the two circuit blocks 100 of the matching circuit 40a have been each coupled in parallel between the node between the high frequency power supply 36 and the electrode on the load side (e.g., the susceptor 16 serving as the lower electrode.) and the ground. However, one circuit block may be coupled to the node in series. An embodiment in this case will be explained below as an alternative example. Note that the plasma processing apparatus 1 according to the alternative example is similar to the plasma processing apparatus 1 according to the embodiment explained above, and the explanations of those configurations and operation that may be duplicated are omitted.

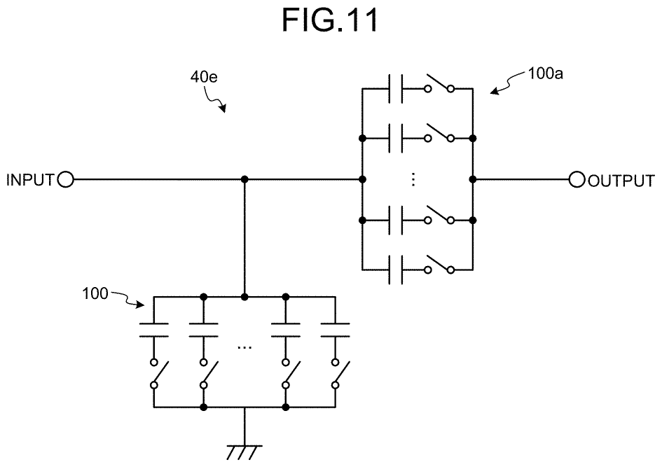

FIG. 11 is a view illustrating an example of a matching circuit of a matcher according to the alternative example. As illustrated in FIG. 11, the alternative example includes a matching circuit 40e, instead of the matching circuit 40a, compared with the embodiment explained above. Note that, in the matching circuit 40e in FIG. 11, the capacitors 123, 124 are omitted. Furthermore, the matching circuit 40e may surround a coil.

The matching circuit 40e includes the circuit block 100 and a circuit block 100a that is the circuit block 100 coupled to a node in series. In the matching circuit 40e, the circuit block 100 and the circuit block 100a are coupled in order from the Input side to which the high frequency power supply 36 is coupled. The susceptor 16 is coupled, via the electric conductor 44, to an Output side of the circuit block 100a.

Similar to the embodiment explained above, the circuit block 100 is coupled in parallel between the node between the high frequency power supply 36 and the electrode on the load side (e.g., the susceptor 16 serving as the lower electrode.) and the ground. The circuit block 100a is coupled in series to the node between the circuit block 100 and the Output side. An internal configuration of the circuit block 100a is similar to that of the circuit block 100, and its explanation is omitted. Even when the matching circuit 40e explained above is used, it is possible to cause an impedance on the load side to match to the output impedance of the high frequency power supply 36, similar to the case when the matching circuit 40a is used.

According to the present embodiment explained above, the plasma processing apparatus 1 includes the chamber 10, a substrate support (the supporting stand 14, the susceptor 16, and the electrostatic chuck 18) that is disposed in the chamber 10, a first electrode (the susceptor 16) disposed in the substrate support, a matcher (40, 42) coupled to the first electrode, a high frequency power supply (36, 38) coupled to the matcher, and a control part (the main control part 70). The matcher includes the lower circuit 102 in which the lower series circuits 101 each including the capacitor 101c and the switching element 101s are coupled to each other in parallel and the upper circuit 104 in which the upper series circuits 103 each including the capacitor 103c and the switching element 103s are coupled to each other in parallel. The control part is configured to control the matcher to set the switching element in each of the lower series circuits 101 or the upper series circuits 103 to the on state or the off state to set one circuit of the lower circuit 102 or the upper circuit 104. The control part is configured to control the matcher to wait until an amount of change in impedance viewed from the matcher toward the chamber becomes stable, which changes depending on the setting of the lower circuit 102 or the upper circuit 104. The control part is configured to control the matcher to set the switching element in each of the lower series circuits 101 or the upper series circuits 103 to the on state or the off state to set another circuit, which differs from the one circuit, of the lower circuit 102 or the upper circuit 104. As a result, it is possible to secure stable plasma, and to promptly attain matching.

Furthermore, according to the present embodiment, a period of time for the waiting corresponds to a period of time required for an impedance to reach 80% or more of a steady state value. As a result, it is possible to secure stable plasma.

Furthermore, according to the present embodiment, the period of time for the waiting is 350 μs or longer. As a result, it is possible to secure stable plasma.

Furthermore, according to the present embodiment, the control part is configured to set, simultaneously or one by one, the switching elements in the lower series circuits 101 or the upper series circuits 103 to the on state or the off state. As a result, it is possible to secure stable plasma, and to promptly attain matching.

Furthermore, according to the present embodiment, the matcher includes a plurality of pairs of the lower circuit 102 and the upper circuit 104 (the circuit blocks 100), and the pairs are each coupled in parallel between the node between the high frequency power supply and the first electrode, and the ground. As a result, it is possible to secure stable plasma, and to promptly attain matching.

Furthermore, according to the present embodiment, the matcher includes a plurality of pairs of the lower circuit 102 and the upper circuit 104, and the pairs include a parallel-coupled pair coupled in parallel between the ground and the node between the high frequency power supply and the first electrode, and a series-coupled pair coupled in series between the high frequency power supply and the first electrode. As a result, it is possible to secure stable plasma, and to promptly attain matching.

Furthermore, according to the present embodiment, a second electrode (the upper electrode 46) facing the first electrode is further included, and the matcher is coupled to each of the first electrode and the second electrode. As a result, it is possible to secure stable plasma, and to promptly attain matching.

It should be conceivable that the embodiment disclosed herein is illustrative in all respects and is not limiting. For the embodiment explained above, there may be omissions, replacements, and alterations in various forms without departing from its range and scope explained in the claims.

Furthermore, it has been explained, in the above embodiment, the case where switching of the capacitors to take place is divided into two times, that is, switching of the capacitors takes place in the lower circuit 102 and the upper circuit 104, in each of the circuit blocks 100. However, the present invention is not limited to the embodiment explained above. For example, if a capacitance value greatly differs before and after switching, switching of the capacitors to take place may be divided into three or more times.

Furthermore, in the embodiment explained above, the high frequency power supplies 36, 38 have been respectively coupled to the susceptor 16 via the matchers 40, 42. However, the present invention is not limited to the embodiment explained above. For example, the high frequency power supply 36 may be coupled, via the matcher 40, to the upper electrode 46, and the high frequency power supply 38 may be coupled, via the matcher 42, to the susceptor 16.

It should be conceivable that the plasma processing apparatus according to the embodiment disclosed herein is illustrative in all respects and is not limiting. It is possible to alter and improve the embodiment in various forms without departing from its range and scope explained in the claims. Those items explained in the above embodiment are able to take other configurations without departing from a range where no inconsistency arises, and are able to be combined within a range where no inconsistency arises.

For example, a capacitively coupled plasma (CCP) type plasma processing apparatus has been explained as an example plasma processing apparatus A plasma processing apparatus may be such a device used to perform a predetermined process (e.g., a film forming process and an etching process) on a substrate. Applications to which the present invention is applied are not limited to plasma processing apparatus.

As the plasma processing apparatus disclosed herein, it is possible to apply it to devices of any type such as atomic layer deposition (ALD) devices, inductively coupled plasma (ICP), radial line slot antenna (RLSA), electron cyclotron resonance plasma (ECR), and helicon wave plasma (HWP).

According to the present disclosure, it is possible to secure stable plasma, and to promptly attain matching.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A plasma processing apparatus comprising:
a chamber;
a substrate support disposed in the chamber;
a first electrode disposed in the substrate support;
a matcher coupled to the first electrode;
a high frequency power supply coupled to the matcher; and
a control part, wherein
the matcher includes
a lower circuit in which a plurality of lower series circuits each including a capacitor and a switching element are coupled to each other in parallel, and
an upper circuit in which a plurality of upper series circuits each including a capacitor and a switching element are coupled to each other in parallel,
the control part is configured to control the matcher to set the switching element in each of the lower series circuits or the upper series circuits to an on state or an off state to set one circuit of the lower circuit or the upper circuit,
the control part is configured to control the matcher to wait until an amount of change in impedance viewed from the matcher toward the chamber becomes stable, the impedance changing depending on the setting of the lower circuit or the upper circuit, and
the control part is configured to control the matcher to set the switching element in each of the lower series circuits or the upper series circuits to the on state or the off state to set another circuit of the lower circuit or the upper circuit, the other circuit being different from the one circuit.

2. The plasma processing apparatus according to claim 1, wherein a period of time for the waiting corresponds to a period of time required for the impedance to reach 80% or more of a steady state value.

3. The plasma processing apparatus according to claim 1, wherein the period of time for the waiting is 350 μs or longer.

4. The plasma processing apparatus according to claim 1, wherein the control part is configured to set, simultaneously or one by one, the switching elements in the lower series circuits or the upper series circuits to the on state or the off state.

5. The plasma processing apparatus according to claim 1, wherein the matcher includes a plurality of pairs of the lower circuit and the upper circuit, the pairs each being coupled in parallel between a node between the high frequency power supply and the first electrode, and a ground.

6. The plasma processing apparatus according to claim 1, wherein the matcher includes a plurality of pairs of the lower circuit and the upper circuit, the pairs including a parallel-coupled pair coupled in parallel between a ground and a node between the high frequency power supply and the first electrode, and a series-coupled pair coupled in series between the high frequency power supply and the first electrode.

7. The plasma processing apparatus according to claim 1, further comprising a second electrode facing the first electrode, wherein
the matcher is coupled to each of the first electrode and the second electrode.

8. A plasma processing method used in a plasma processing apparatus,
the plasma processing apparatus comprising:
a chamber;
a substrate support disposed in the chamber;
a first electrode disposed in the substrate support;
a matcher coupled to the first electrode, the matcher including a lower circuit in which a plurality of lower series circuits each including a capacitor and a switching element are coupled to each other in parallel and an upper circuit in which a plurality of upper series circuits each including a capacitor and a switching element are coupled to each other in parallel; and
a high frequency power supply coupled to the matcher,
the plasma processing method comprising:
setting the switching element in each of the lower series circuits or the upper series circuits to an on state or an off state to set one circuit of the lower circuit or the upper circuit;
waiting until an amount of change in impedance viewed from the matcher toward the chamber becomes stable, the impedance changing depending on the setting of the lower circuit or the upper circuit; and
setting the switching element in each of the lower series circuits or the upper series circuits to the on state or the off state to set another circuit of the lower circuit or the upper circuit to control the matcher, the other circuit being different from the one circuit.
